(19) United States
(12) Patent Application Publication
(10) Pub. No.: US 2025/0318339 A1
(43) Pub. Date: Oct. 9, 2025

(54) LED DISPLAY INSTALLATION SYSTEM AND LED DISPLAY INSTALLATION METHOD

(71) Applicant: AI PIXEL USA INC, ORLANDO, FL (US)

(72) Inventors: HUJUN LIU, Shenzhen (CN); YIFU LIU, Shenzhen (CN); YIFENG LIU, Shenzhen (CN)

(21) Appl. No.: 19/023,690

(22) Filed: Jan. 16, 2025

(30) Foreign Application Priority Data
Apr. 8, 2024 (CN) 202410414784.6
Sep. 29, 2024 (CN) 202411376655.9

(51) Int. Cl. H10H 29/01; G09F 9/302; H05K 5/02

(52) U.S. Cl. CPC H10H 29/036; G09F 9/3026; H05K 5/0221

(57) ABSTRACT

An LED display installation system and an LED display installation method are provided. The LED display installation system includes a plurality of display screen installation frames, each display screen installation frame can be installed with an LED display screen; adjacent display screen installation frames are connected through a combination of a curvature lock component and a U-shaped lock component; a third installation side of the display screen installation frames is provided with at least one fastening part, a fourth installation side thereof is provided with at least one second U-shaped lock component. Adjacent display screen installation frames are assembled or dissembled by a cooperation of the fastening part and the second U-shaped lock component; the display screen installation frames are connected horizontally through the first and second installation sides, connected vertically through third and fourth installation sides, and assembled into a support frame for a large LED display screen.

### CROSS-REFERENCE TO RELATED APPLICATIONS

This application claims priority to Chinese Patent Application No. 202411376655.9, filed on Sep. 29, 2024 and Chinese Patent Application No. 202410414784.6, filed on Apr. 8, 2024. Both are hereby incorporated by reference in their entireties.

### TECHNICAL FIELD

The present disclosure relates to the field of LED display installation system technologies, and in particular, to an LED display installation system and an LED display installation method.

### BACKGROUND

A large LED display screen requires assembling a plurality of modular LED display modules. The LED display screen box frame of this solution is used to fix each LED display module and assemble all LED display modules into a large LED display screen.

The connection structure of the existing LED display box frame usually uses conventional connection ways such as bolts, which results in a huge assembly workload for large LED displays. Moreover, due to the possibility of high-altitude operations involved in the assembly work, the huge workload also brings high risks to the assembly process. Therefore, the assembly way of the existing LED display box frame urgently needs to be improved.

### SUMMARY

The purpose of the present disclosure is to provide an LED display screen installation system that addresses the shortcomings of the existing technologies mentioned above.

According to embodiment of the present disclosure, a first aspect of the present disclosure provides an LED display screen installation system, including a plurality of display installation frames, and each display installation frame is capable of installing an LED display screen;
the display screen installation frames include a first installation side and a second installation side; the first installation side of the display screen installation frames is provided with at least one curvature lock component, the second installation side of the display screen installation frames is provided with at least one U-shaped lock component; adjacent display screen installation frames are connected through a cooperation of the curvature lock component and the U-shaped lock component;
the display screen installation frames further include a third installation side and a fourth installation side; the third installation side of the display screen installation frames is provided with at least one fastening part, the fourth installation side thereof is provided with at least one second U-shaped lock component; adjacent display screen installation frames are assembled or disassembled by a cooperation of the fastening part and the second U-shaped lock component;
the plurality of display screen installation frames are connected horizontally through the first installation side and the second installation side, are connected vertically through the third installation side and the fourth installation side, and are assembled into a support frame for a large LED display screen.

In some embodiments of the present disclosure, rears of the display screen installation frames are further provided with an LED display screen box windproof bracket, which includes a main suspension frame on the same plane and an auxiliary bracket provided at one side of the main suspension frame; the auxiliary bracket is accommodated in the plane of the main suspension frame, the main suspension frame is capable of being unfolded and fixed in an unfolded posture to form a three-dimensional support mechanism.

In some embodiments of the present disclosure, the display screen installation frames are capable of installing an LED display screen carrier, and the LED display screen carrier includes a carrier body; a bearing surface of the carrier body is provided with a plurality of first positioning structures, the first positioning structures are adapted to a second positioning structure of modular load-bearing objects; two opposite sides of the modular load-bearing objects are respectively provided with the first positioning structures and the second positioning structure; adjacent modular load-bearing objects are spliced together through the first positioning structures and the second positioning structure.

In some embodiments of the present disclosure, the system further includes a carrier body, a bearing surface of the carrier body is provided with a plurality of first positioning structures, which are adapted to a second positioning structure of modular load-bearing objects;

two opposite sides of the modular load-bearing objects are respectively provided with the first positioning structures and the second positioning structure, adjacent modular load-bearing objects are spliced together through the first positioning structures and the second positioning structure.

According to the embodiments of the present disclosure, using the LED display installation system provided in the first aspect of the present disclosure, a second aspect is provided as follows.

An installation method for an LED display screen, including the following steps:
obtaining a position of a suspension beam and sequentially installing display screen installation frames along a vertical direction below the suspension beam, where the display screen installation frames are capable of installing an LED display screen, the display screen installation frames include a first installation side and a second installation side, the first installation side of the display screen installation frames is provided with at least one curvature lock component, the second installation side of the display screen installation frames is provided with at least one U-shaped lock component, adjacent display screen installation frames are connected through a cooperation of the curvature lock component and the U-shaped lock component;
a bottom of the suspension beam is provided with a curvature lock component that is the same as the first installation side of the display screen installation frames; the display screen installation frames are connected through a corporation of the curvature lock component and the U-shaped lock component; or
a bottom of the suspension beam is provided with a U-shaped lock component that is the same as the second installation side of the display screen installation frames, and the display screen installation frames are connected through a cooperation of the curvature lock component and the U-shaped lock component;
defining a hierarchical order of the display screen installation frame for each installation of one display screen installation frame, connecting horizontally and fixing the display screen installation frames of the same hierarchical order; the display screen installation frames further include a third installation side and a fourth installation side; the third installation side of the display screen installation frames is provided with at least one fastening part, the fourth installation side thereof is provided with at least one second U-shaped lock component; adjacent display screen installation frames are assembled or disassembled through a cooperation of the fastening part and the second U-shaped lock component;
connecting all display screen installation frames in sequence and assembling them into a support frame for a large LED display screen; when each display screen installation frame is installed with an LED display screen, a large LED display screen is assembled.

Compared with existing technologies, the beneficial effect of the technical solution provided in the present application is that it can directly and sequentially splice LED display screen modules downwards on the suspension beam. Due to the same connection structure set at the bottom of the suspension beam as the display screen installation frames, using the same connection structure as the display screen installation frames can save design and production costs of the suspension beam, and an overall connection operation is consistent, thereby avoiding errors, and ultimately achieving efficient, fast, and safe installation and removal of large LED displays.

Design the display box frame for installing LED display modules as identical unit modules, so that there is no need to distinguish between left and right positions or up and down positions. During installation, removal, and transportation, there is no need to classify them, and there will be no misoperation caused by incorrect differentiation.

Besides that, the display box frame of each unit module is divided into a first installation side and a second installation side. The first installation side and the second installation side are cooperating with each other. When correctly distinguished a connection surface facing the LED display screen, the first installation side of each unit module is directly facing the second installation side of an adjacent unit module, and the second installation side of each unit module is also directly facing the first installation side of another adjacent unit module. In the overall installation system of the LED display screen, the installation and removal operations of each unit module are the same, and the efficiency of repeated operations by an operator can be guaranteed. Consistent operation can also reduce a probability of misoperation.

Furthermore, the display box frame of each unit module is divided into a third installation side and a fourth installation side. The third installation side and the fourth installation side are cooperating with each other. When correctly distinguished the connection surface facing the LED display screen, the third installation side of each unit module is directly facing the fourth installation side of an adjacent unit module, and the third installation side of each unit module is also directly facing the fourth installation side of another adjacent unit module. In the overall installation system of the LED display screen, the installation and removal operations of each unit module are the same, and the efficiency of repeated operations by the operator can be guaranteed. Consistent operation can also reduce the probability of misoperation.

The display screen installation frames of adjacent unit modules are connected through the combination of curvature lock components and U-shaped lock components. The combination of U-shaped lock components and curvature lock components ensures the connection strength, stability, and installation/removal efficiency of the overall LED display screen installation system. The curvature lock component adjusts a splicing angle between adjacent LED display screen box frames, thereby achieving the splicing of large LED display.

The windproof bracket is set to a containment state and an unfolded state. In the containment state, it coincides with a height of an original display screen box, without taking up too much space or changing a basic equipment for transportation, storage, and installation of the existing display screen box. In the unfolded state, the windproof bracket forms a three-dimensional support mechanism, which adds at least one layer of installation support structure to the original flat display screen and display screen installation frame system, expanding the planar support into a three-dimensional support, greatly enhancing the wind resistance and deformation resistance of large LED display screens. The design concept of the windproof bracket and the display screen installation frames is consistent, both using the same unit module, so there is no need to distinguish left and right or left and right positions. During installation, removal, and transportation, there is no need to classify them, and there will be no misoperation caused by incorrect differentiation. By providing the windproof bracket, the gravity center of the display screen support system has moved back to the main suspension frame, rendering the overall weight distribution more balanced and reasonable. When the windbreak frame is deployed, it forms a stable ladder structure for a worker to climb up and down, thereby providing more operational space when needed.

### BRIEF DESCRIPTION OF DRAWINGS

In order to provide a clearer explanation of the embodiments of the present disclosure or the technical solutions in the prior art, a brief introduction will be given to the accompanying drawings required for the description of the embodiments or the prior art. It is obvious that the accompanying drawings described below are only some embodiments of the present disclosure. For those skilled in the art, other drawings can be obtained based on these drawings without creative work.

FIG. 1 is a schematic diagram of a left structure and a right structure of a display screen installation frame in an embodiment.

FIG. 2 is a schematic diagram of a left-and-right connection of adjacent display screen installation frames in an embodiment.

FIG. 3 is a schematic structural diagram of a curvature lock component and a U-shaped lock component in an embodiment.

FIG. 4 is a schematic diagram of connection and cooperation between the curvature lock component and the U-shaped lock component in an embodiment.

FIG. 5 is a schematic diagram of an up-and-down structure of the display screen installation frame in an embodiment.

FIG. 6 is a schematic diagram of an up-and-down connection between adjacent display screen installation frames in an embodiment.

FIG. 7 is a schematic structural diagram of a fastening part and the U-shaped lock component in an embodiment.

FIG. 8 is a structural diagram of a LED display screen box windproof bracket in an embodiment.

FIG. 9 is a schematic diagram of a containment state of the windproof bracket in an embodiment.

FIG. 10 is an overall schematic diagram of an LED display screen carrier in an embodiment.

Numeral reference: 100 display installation frame; 10 curvature lock component; 101 first docking board; 102 locking buckle; 103 locking groove; 20 U-shaped lock component; 201 second docking board; 202 lock body; 203 U-shaped connection rod; 204 handle; 205 insurance deduction; 207 first rotation axis; 208 second rotation axis; 30 fastening part; 301 buckle board; 302 buckle groove; 40 second U-shaped lock component; 401 lock body; 402 U-shaped connection rod; 403 handle; 404 insurance deduction; 51 first fixed rod; 52 second fixed rod; 53 upper component; 54 lower component; 55 latch block; 61 support rod; 62 connection arm; 63 sliding arm rod; 641 knob sleeve; 642 screw; 500 box windproof bracket; 70 carrier body.

### DESCRIPTION OF EMBODIMENTS

In order to enable technical personnel in this field to better understand the technical solutions in the present application, the following will provide a clear and complete description of the technical solutions in the embodiments of the present application in combination with the accompanying drawings. Obviously, the described embodiments are only a part of the embodiments of the present application, not all of them. Based on the embodiments in the present application, all other embodiments obtained by those skilled in the art without creative work are within the protection scope of the present application.

This embodiment involves an assembly and splicing device for a large LED display system. The large LED displays usually use a plurality of small modular LED display modules (small LED displays). The large LED displays need to be quickly assembled and disassembled in many scenarios, such as concerts held in sports stadiums, which are rented according to time. During a stage construction process, the installation and removal time of large LED displays are counted as rental time. It is extremely difficult to quickly complete installation or disassembly within a limited time while ensuring the installation accuracy and stability of large LED displays. A relatively conservative and stable installation or disassembly process represents the need to rent more venue time and higher costs.

In order to improve installation or disassembly speed of the large LED display screens, the existing solution is to pre-fix the small LED display module of the large LED display screen equipment on display screen installation frames 100, and quickly assemble the

LED display module on site through splicing the display screen installation frames 100. However, the splicing operation of the existing display screen installation frames 100 is relatively complex, resulting in insufficient installation efficiency. Due to limited on-site operation time, it not only causes great work pressure for operators, but also poses installation errors and high-altitude operation risks due to the difficulty and workload of operation.

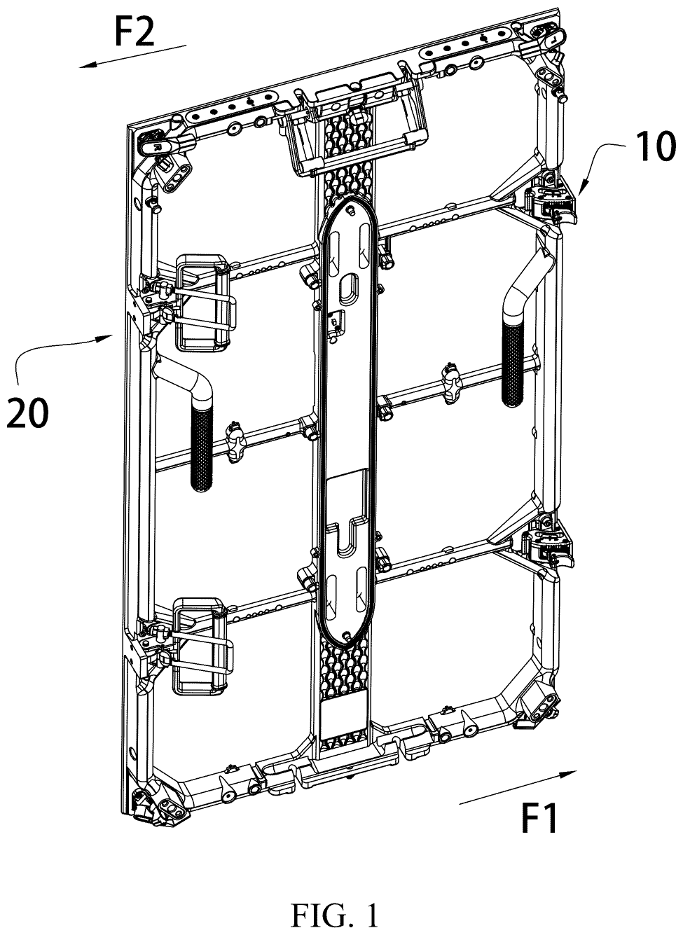

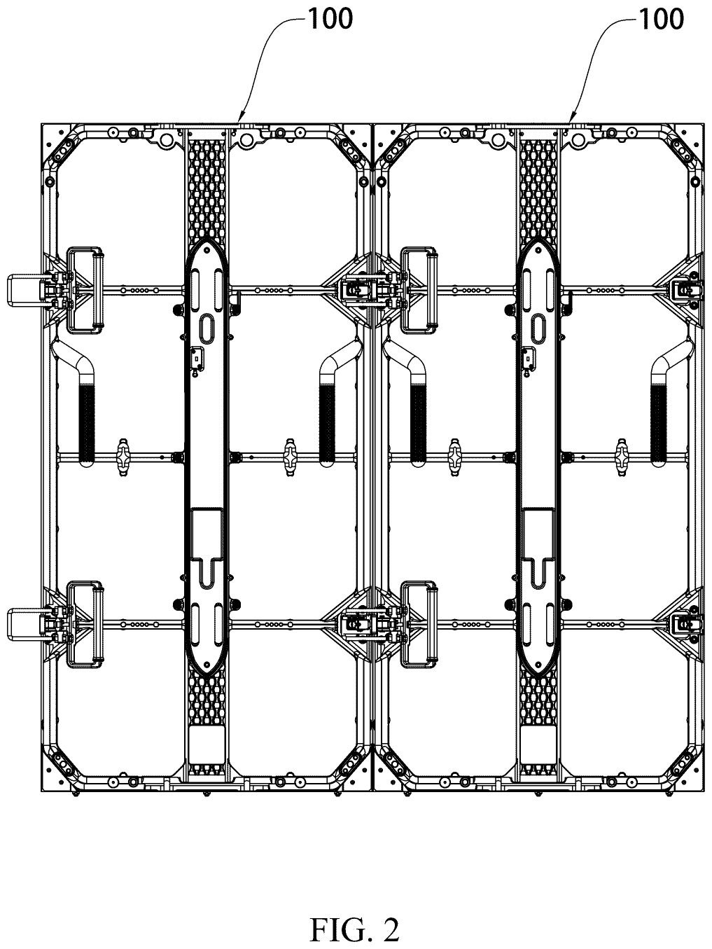

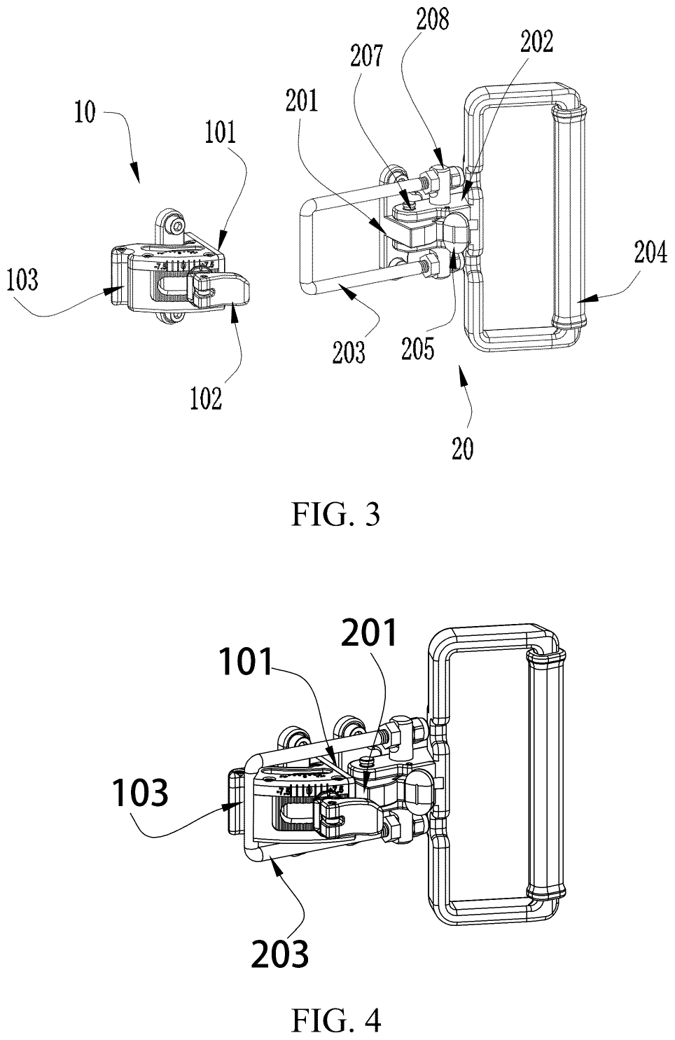

In order to solve the above problems, this embodiment provides a left-and-right connection device for an LED display screen box frame, which includes display screen installation frames 100. Each display screen installation frame 100 can install an LED display screen, as shown in FIGS. 1-4. The display screen installation frames 100 include a first installation side (F1 direction) and a second installation side (F2 direction). The first installation side of the display screen installation frames 100 is provided with at least one curvature lock component 10, and the second installation side of the display screen installation frames 100 is provided with at least one U-shaped lock component 20. Adjacent display screen installation frames 100 are connected through a cooperation of the U-shaped lock component 20 and the curvature lock component 10.

By using the left-and-right connection device of the LED display screen box frames in this embodiment, the display screen box frames provided with the LED display module is designed as identical unit modules, so there is no need to distinguish left and right positions, and there is no need to classify during installation, removal, and transportation, nor will there be any misoperation caused by incorrect differentiation. A display box frame of each unit module is divided into a first installation side and a second installation side. The first installation side and the second installation side are cooperating with each other. When correctly distinguished a connection surface facing the LED display screen, the first installation side of each unit module faces the second installation side of an adjacent unit module, and the second installation side of each unit module also faces the first installation side of another adjacent unit module. In the overall installation system of the LED display screen, the installation and removal operations of each unit module are the same, and the efficiency of repeated operations by the operator can be guaranteed. Consistent operation can also reduce a probability of misoperation. The display screen installation frames 100 of adjacent unit modules are connected through the cooperation of the curvature lock component 10 and the U-shaped lock component 20. The U-shaped lock component 20 cooperates with the curvature lock component 10 to ensure the connection strength, stability, and installation/removal efficiency of the overall LED display screen installation system. The curvature lock component 10 adjusts a splicing angle between adjacent LED display screen box frames, thereby achieving the splicing of large LED displays.

In an implementation mode, the curvature lock component 10 includes a first docking board 101, and the U-shaped lock component 20 includes a second docking board 201 that cooperates with the first docking board 101. The curvature lock can adjust an angle of the first docking board 101 relative to the display screen installation frame 100. In a locked connection state of adjacent display screen installation frames 100, the first docking board 101 and the second docking board 201 are tightly adhered.

The adjacent display screen installation frames 100 are connected by the curvature lock component 10 and the U-shaped lock component 20. Therefore, it is necessary to design new curvature lock components 10 and U-shaped lock components 20 to simplify the disassembly and assembly process between the display screen installation frames 100, while also increasing the connection strength between the display screen installation frames 100 and achieving angular connection between them. Moreover, the splicing of arc LED display screen can be achieved through the angular connection between the display screen installation frames 100, which is extremely difficult to implement.

In order to achieve a quick connection between the curvature lock component 10 and the U-shaped lock component 20, this embodiment designs a U-shaped lock component 20, which include a lock body 202, a U-shaped connection rod 203, a handle 204, and an insurance deduction 205. At the same time, the curvature lock component 10 includes a locking groove 103 that cooperates with the U-shaped connection rod 203. The connection and disassembly between adjacent display screen installation frames 100 are realized as simple operations of the U-shaped connection rod 203 being fastened into and removed from the locking groove 103. At the same time, when adjusting an angle of the first docking board 101 to adjust the connection angle of adjacent display screen installation frames 100, it does not affect the operation of the U-shaped connection rod 203 being fastened into and removed from the locking groove 103 at all.

In an implementation mode, the second docking board 201 can be connected to a lock body of the U-shaped lock component 20, or the second docking board 201 can be fixedly set on the display screen installation frames 100.

In an implementation mode, the lock body 202 is connected to the display screen installation frames 100 through a first rotation axis 207, and the U-shaped connection rod 203 is connected to the lock body 202 through a second rotation axis 208. In a pre-splicing state of adjacent display screen installation frames 100, the insurance deduction 205 is opened to rotate the U-shaped connection rod 203 of the U-shaped lock component 20 in a first rotation direction, so that a U-shaped end is limited in a locking groove 103 of the curvature lock component 10. The second rotation axis 208 is driven by the handle 204 to rotate the U-shaped connection rod 203 in a second rotation direction, so that a second connection shaft end reverses and enters a locking position, thereby forming a locked connection state of adjacent display screen installation frames 100. The second rotation direction is opposite to the first rotation direction.

In order to achieve the connection strength between the display screen installation frames 100, the curvature lock component 10 is docked and connected to the U-shaped lock component 20, and the stable connection between brackets of adjacent display screen installation frames 100 is achieved through a cooperation between the first docking board 101 and the second docking board 201. The curvature lock component 10 includes a first docking board 101, and the U-shaped lock component 20 includes a second docking board 201 that cooperates with the first docking board 101. The curvature lock can adjust an angle of the first docking board 101 relative to the display screen installation frames 100. In a locked connection state of adjacent display screen installation frames 100, the first docking board 101 and the second docking board 201 are tightly adhered.

In addition, the first docking board 101 is provided with at least one positioning pin, and the second docking board 201 is provided with a positioning slot that is compatible with the position and number of the positioning pins. In a pre-splicing state of the adjacent display screen installation frames 100, a positioning pin is inserted into the positioning slot to limit a relative displacement between the first docking board 101 and the second docking board 201. A matching structure between the positioning pin and the positioning slot facilitates a correct splicing of adjacent display screen installation frames 100 in the pre-splicing state of the adjacent display screen installation frames 100.

In order to achieve the angular connection between the display screen installation frames 100, in this embodiment, the first docking board 101 is connected to the curvature lock, and the second docking board 201 is arranged in the U-shaped lock component 20 on the second installation side of the display screen installation frame 100. A surface of the display screen installation frames 100 facing the LED display screen is defined as a connection surface, and the second docking board 201 of the U-shaped lock component 20 is perpendicular to the connection surface. When the curvature lock component 10 is adjusted to 0 degree, the first docking board 101 is perpendicular to the connection surface.

In an implementation mode, the curvature lock component 10 includes a locking buckle 102. In an open state of the locking buckle 102, adjustment angles of the curvature lock component 10 include −7.5°, −5°, −2.5°, 0°, 2.5°, −5°, and −7.5°. An angle range between the first docking board 101 and the connection surface adjusted through the curvature lock includes −7.5°, −5°, −2.5°, 0°, 2.5°, −5°, and −7.5°, thereby an angle range between adjacent display modules of a large LED display screen that can be adjusted includes −7.5°, −5°, −2.5°, 0°, 2.5°, −5°, and −7.5°. That is, the arc LED display screen is pre-calculated and implemented as curvature adjustment of the curvature lock component 10, and precise curvature adjustment is achieved through curvature scales on the curvature lock and positioning of curvature adjustment tooth on the curvature lock. Finally, during a fast installation process of the display screen installation frames 100, the operator can quickly adjust the curvature of the curvature lock at a required position to achieve the splicing of the arc LED display screen.

In an implementation mode, an overall area of the display screen installation frames 100 is slightly smaller than that of the LED display screen. After the adjacent display screen installation frames 100 are connected, there is a gap between the display screen installation frames 100, but the LED display screens at a front end are tightly spliced together.

In order to achieve fast, accurate, and convenient connection between adjacent display screen installation frames 100, at least one positioning pin is provided on the first installation side of the display screen installation frames 100, and a positioning slot that matches the number, position, and structure of the positioning pins is further provided on the second installation side of the display screen installation frames 100.

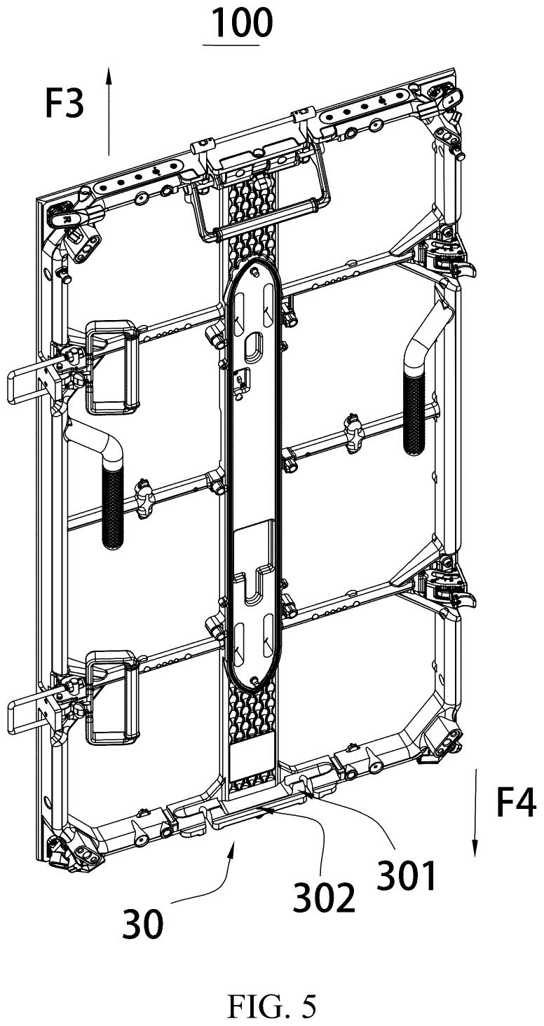

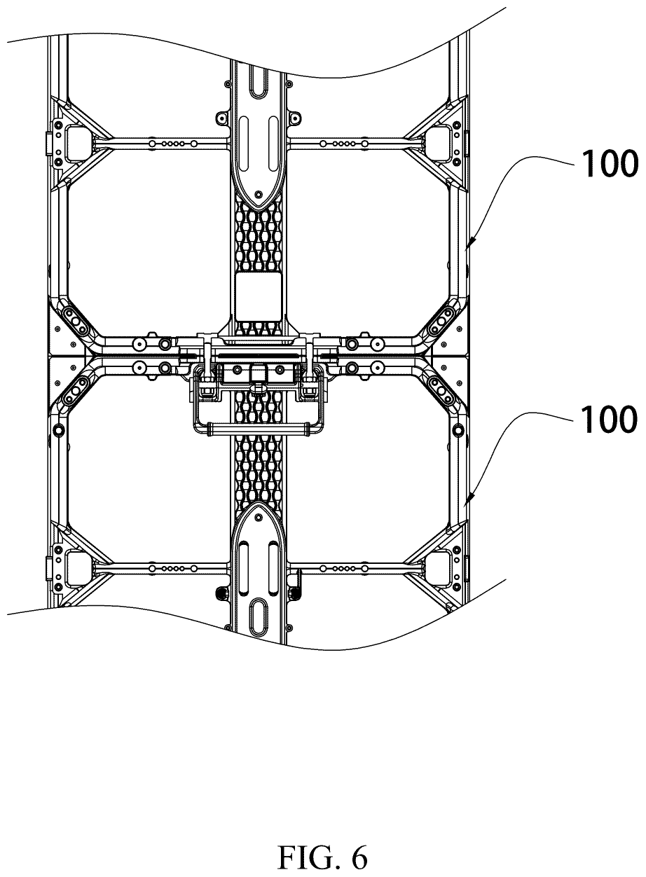

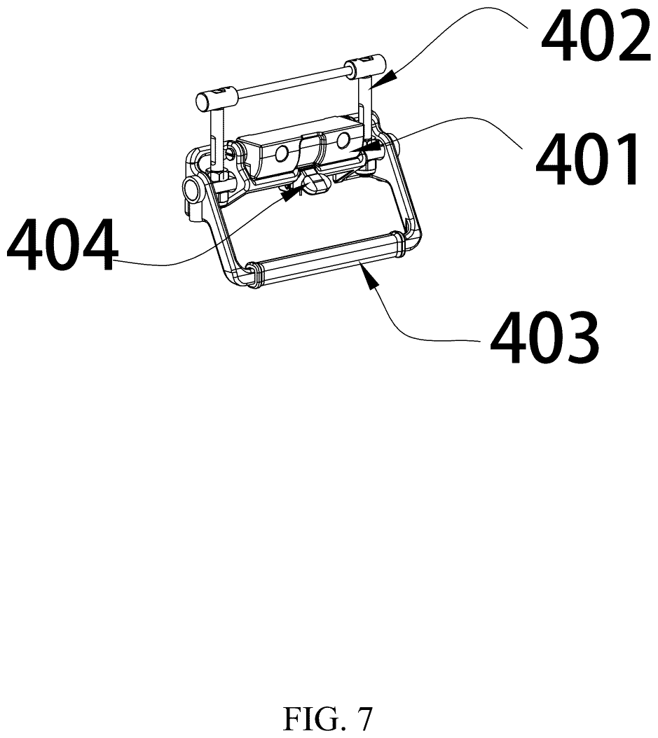

As shown in FIGS. 5-7, an up-and-down connection device for an LED display screen box frame includes display screen installation frames 100, each display screen installation frame 100 can install an LED display screen, the display screen installation frames 100 include a third installation side and a fourth installation side, the third installation side of the display screen installation frames 100 is provided with at least one fastening part 30, the fourth installation side thereof is provided with at least one second U-shaped lock component 40; adjacent display screen installation frames 100 are connected to a cooperation of the fastening part 30 and the second U-shaped lock component 40.

The fastening part 30 includes a buckle board 301, and the buckle board 301 is integrally formed with the display screen installation frames 100, or the buckle board 301 is provided on the display screen installation frames 100. In a locked connection state of adjacent display screen installation frames 100, the second U-shaped lock component 40 is fixedly connected to the buckle board 301. The buckle board 301 includes a buckle groove 302 that is compatible with the second U-shaped lock component 40.

A lock body 401 is connected to the display screen installation frames 100 through a first rotation axis, and the U-shaped connection rod 402 is connected to the lock body 401 through a second rotation axis. In a pre-spicing state of adjacent display screen installation frames 100, an insurance deduction 404 is opened, and the U-shaped connection rod 402 of the second U-shaped lock component 40 is rotated in the first rotation direction to limit the U-shaped end in the buckle groove 302 of the fastening part 30. The second rotating shaft is driven by a handle 403 to rotate the U-shaped connection rod 402 in the second rotation direction to reverse the second connecting shaft end and enter the locking position, thereby forming the locked connection state of adjacent display screen installation frames 100. The second rotation direction is opposite to the first rotation direction.

The overall area of the display screen installation frames 100 is slightly smaller than that of the LED display screen.

Firstly, the display box frame for installing LED display modules should be designed as identical unit modules, so that there is no need to distinguish top and bottom positions, and there is no need to classify them during installation, removal, and transportation, nor will there be any misoperation caused by incorrect differentiation.

Secondly, the display box frame of each unit module is divided into a third installation side and a fourth installation side. The third installation side and the fourth installation side are cooperating with each other. When correctly distinguished the connection surface facing the LED display screen, the third installation side of each unit module is directly facing the fourth installation side of an adjacent unit module, and the third installation side of each unit module is also directly facing the fourth installation side of another adjacent unit module. In the overall installation system of the LED display screen, the installation and removal operations of each unit module are the same, and the efficiency of repeated operations by the operator can be guaranteed. Consistent operation can also reduce the probability of misoperation.

Furthermore, the LED display box frames of adjacent unit modules are connected through the combination of the fastening part 30 and the second U-shaped lock component 40. The second U-shaped lock component 40 cooperates with the fastening part 30 to ensure the connection strength, stability, and installation/removal efficiency of the overall LED display installation system.

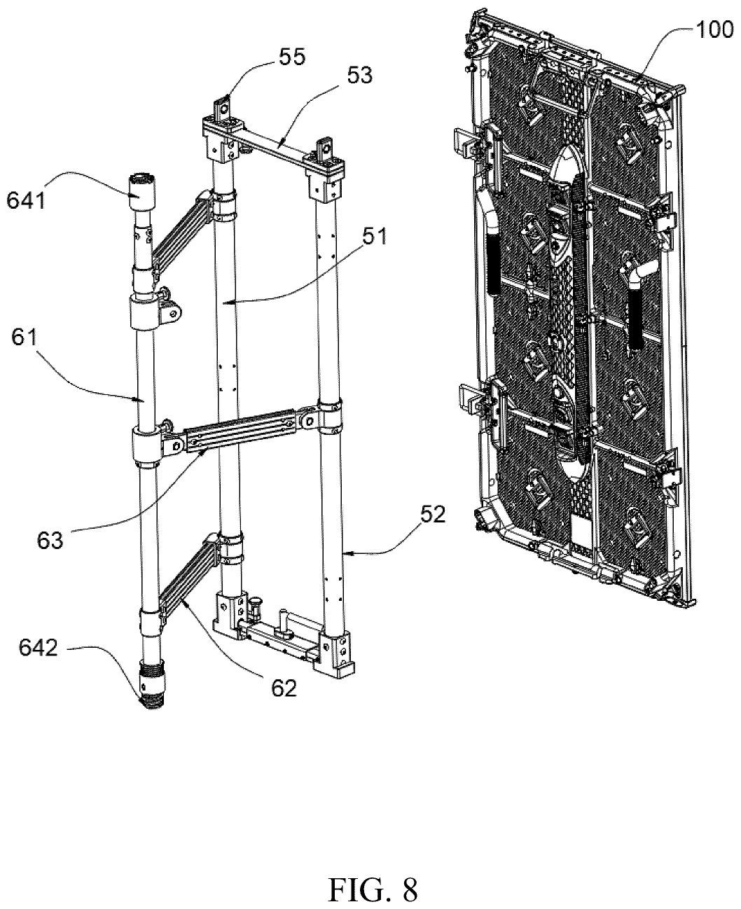

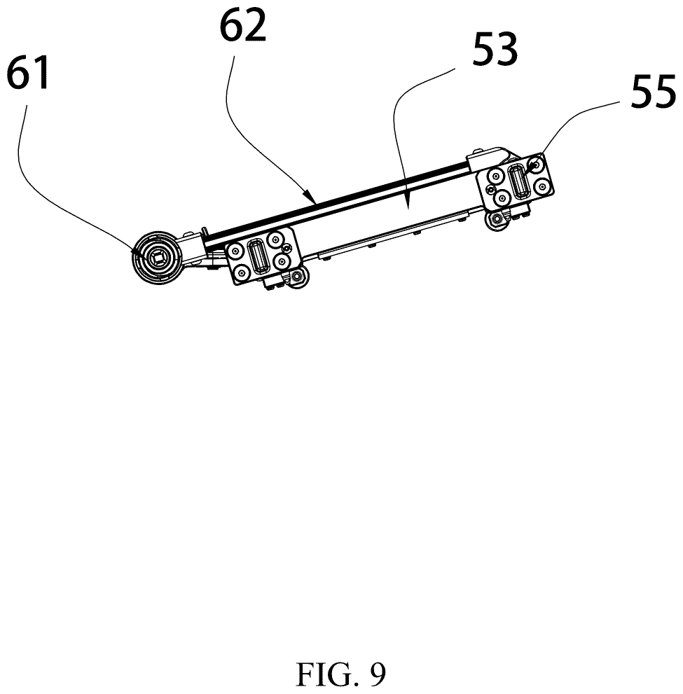

As shown in FIGS. 8-9, this embodiment provides a LED display screen box windproof bracket.

The LED display screen box windproof bracket is provided on rears of the display screen installation frames 100.

The LED display screen box windproof bracket includes a main suspension frame on the same plane and an auxiliary bracket provided on one side of the main suspension frame. The auxiliary bracket can be accommodated in the plane of the main suspension frame, or the main suspension frame can be unfolded independently and fixed in an unfolded posture to form a three-dimensional support mechanism.

In an implementation mode, the display screen installation frames 100 includes an installation surface and a rear surface, and the installation surface of the display screen installation frames 100 is detachably connected to the LED display screen.

In an implementation mode, the main suspension frame includes two fixed rods

that are longitudinally arranged and a crossbar component provided between the two fixed rods.

In an implementation mode, the crossbar component includes an upper component 53 and a lower component 54. The upper component 53 includes at least one latch block 55, and the lower component 54 includes at least one pin slot. The latch block 55 of the LED display box windproof bracket can be fixedly connected to the pin slot of the upper adjacent LED display box windproof bracket, and the pin slot of the LED display box windproof bracket can be fixedly connected to the latch block 55 of the lower adjacent LED display box windproof bracket.

In an implementation mode, the upper component 53 includes two latch blocks 55, and the lower component 54 includes two pin slots. The two latch blocks 55 are respectively arranged concentric with the two fixed rods, and the two pin slots are respectively arranged concentric with the two fixed rods.

In an implementation mode, the latch blocks 55 are provided with a pin hole for locking in the same direction with the crossbar component.

In an implementation mode, the lower component 54 is provided with a switch component, and the switch component is configured to lock or release the latch blocks 55 that is inserted into the pin slots.

In an implementation mode, a plurality of LED display screen box windproof brackets are connected through a cooperation of the upper component 53 and the lower component 54 to form a continuous display screen perpendicular to a bottom surface. The latch blocks 55 of the windproof bracket of a topmost LED display screen box of the continuous display screen is connected to the suspension beam.

In an implementation mode, the auxiliary bracket includes a support rod 61, and the support rod 61 is rotatably connected to one of the fixed rods through two connection arms 62. A sliding arm component is further provided between the support rod 61 and the other fixed rod, the sliding arm component includes a fixed end, a sliding arm rod 63, and a sliding sleeve.

When the auxiliary bracket is accommodated in the plane of the main suspension frame, the sliding sleeve slides upward along the support rod 61 and drives the sliding arm rod 63 to be accommodated on one side of another fixed rod from a vertical direction to a parallel direction. When the auxiliary bracket is unfolded independently form the suspension frame, the sliding sleeve moves downward along the support rod 61 and drives the sliding arm rod 63 to be unfolded from the parallel direction to the vertical direction to one side away from the main suspension frame. When the auxiliary bracket is fixed in an unfolded posture, the sliding sleeve moves down to a limit fixing part and makes the sliding arm rod 63 and the two connection arms 62 in the same direction to form a support ladder that allows a user to crawl. At this time, the support rod 61 and the two fixed rods of the main suspension frame form a three-dimensional support mechanism arranged in a triangle.

In an implementation mode, an upper end of the support rod 61 is provided with a knob sleeve 641, and a lower end of the support rod 61 is provided with a screw 642 that cooperates with the knob sleeve 641 of the adjacent support rod 61.

In an implementation mode, the fixed rods are configured as a first fixed rod 51 and a second fixed rod 52. The support rod 61 is connected to the first fixed rod 51 through two connection arms 62, and is connected to the second fixed rod 52 through a sliding arm component.

The beneficial effects of the technical solution provided in the present application are as following.

Firstly, the windproof bracket is set to a containment state and an unfolded state. In the containment state, it coincides with a height of an original display screen box, without taking up too much space or changing the basic equipment for transportation, storage, and installation of the existing display screen box. In the unfolded state, the windproof bracket forms a three-dimensional support mechanism, which adds at least one layer of installation support structure to the original flat display screen and display screen installation frame system, expanding the planar support into a three-dimensional support, greatly enhancing the wind resistance and deformation resistance of the large LED display screen.

Secondly, the design concept of the windproof bracket 100 and the display screen installation frames is consistent, both of which are the same unit modules, so there is no need to distinguish left and right or left and right positions. During installation, removal, and transportation, there is no need to classify them, and there will be no misoperation caused by incorrect differentiation.

Furthermore, by providing the windproof bracket, the gravity center of the display screen support system has moved back to the main suspension frame, rendering the overall weight distribution more balanced and reasonable.

Besides that, when the windbreak frame is deployed, it forms a stable ladder structure for the worker to climb up and down, thereby providing more operational space when needed.

This embodiment provides an LED display screen carrier, it is a small car that carries an LED display screen, a display screen installation frame, and a display screen box windproof bracket 500. The existing assembly process of large LED display screens uses a large number of display screen installation frames or a large number of box windproof brackets 500. These modular display screen installation frames or box windproof brackets 500 require a large amount of space for storage, transportation, and on-site storage. Especially, there are very high requirements for installation time at the installation site, which requires a large number of devices to be provided quickly and without installation errors. The existing display screen installation frames or box windproof brackets 500 are generally rack structures that are not easy to stack and are prone to cross interference with each other. Therefore, it is very difficult to achieve fast storage, transportation, and installation of display screen installation frames or box windproof brackets 500.

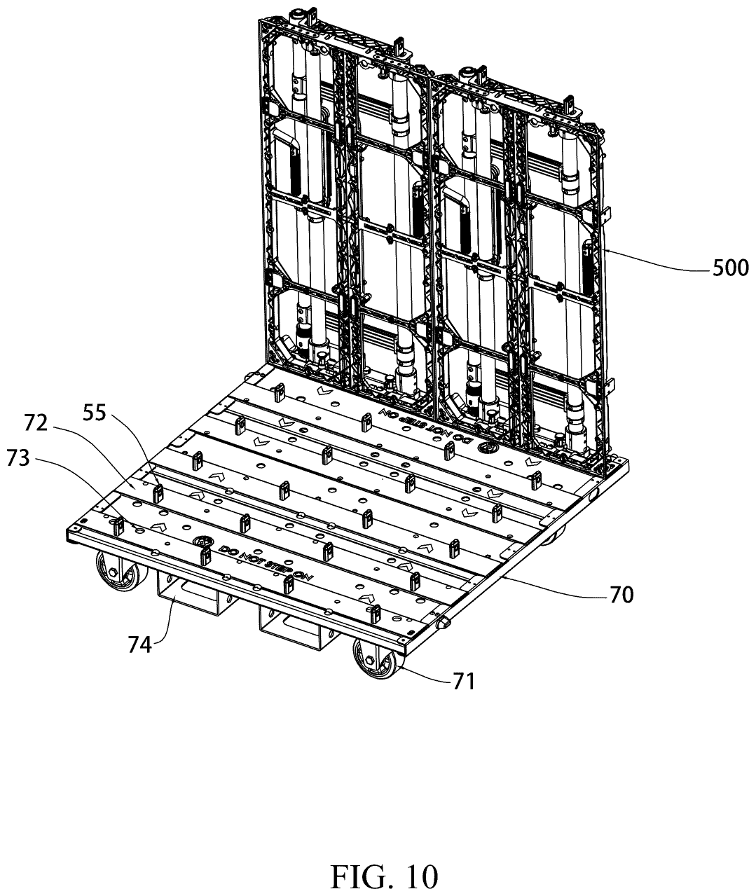

In order to solve the above technical problems, this embodiment provides an LED display screen carrier, as shown in FIG. 10, including:
a carrier body 70, a bearing surface of the carrier body 70 is provided with a plurality of first positioning structures, the first positioning structures are adapted to a second positioning structure of modular load-bearing objects. Two opposite sides of the modular load-bearing objects are respectively provided with the first positioning structures and the second positioning structure, and adjacent modular load-bearing objects are connected to each other through the first positioning structures and the second positioning structure.

Firstly, the carrier body 70 is provided with the first positioning structures, which cooperates with the second positioning structure of the modular load-bearing objects to achieve rapid positioning of the modular load-bearing objects on the carrier body 70.

Secondly, the first positioning structures on the carrier body 70 are consistent with a positioning structure between the modular load-bearing objects, which means that there are already positioning structures that are cooperated with each other between the modular load-bearing objects. The carrier body 70 also uses the same positioning structure, which is equivalent to a modular load-bearing object, but only retains its first positioning structure.

By setting the first positioning structure as described above, the modular load-bearing objects can be directly fixed on the carrier body 70 without the need to design other positioning structures. Moreover, since the first positioning structures have extended the positioning structure of the modular load-bearing objects, the assembly or disassembly process of the modular load-bearing objects are the same as the operation of loading on the carrier body 70, which can also improve the overall assembly efficiency of the display screen and reduce operational errors.

An embodiment provides an installation method for an LED display screen, including the following steps:
obtaining a position of a suspension beam and sequentially installing display screen installation frames 100 along a vertical direction below the suspension beam; where the LED display screens can be provided on the display screen installation frames 100; the display screen installation frames 100 include a first installation side and a second installation side, the first installation side of the display screen installation frames 100 is provided with at least one curvature lock component 10, and the second installation side of the display screen installation frames 100 is provided with at least one U-shaped lock component 20; adjacent display screen installation frames 100 are connected to a cooperation of the curvature lock component 10 and the U-shaped lock component 20;
a bottom of the suspension beam is provided with a curvature lock component 10 that is the same as the first installation side of the display screen installation frame 100; the display screen installation frames 100 are connected through a cooperation of the U-shaped lock component 20 and the curvature lock component 10; or
a bottom of the suspension beam is provided with a U-shaped lock component 20 that is the same as the second installation side of the display screen installation frames; the display screen installation frames are connected through a corporation of the curvature lock component 10 and the U-shaped lock component 20;
defining a hierarchical order of the display screen installation frame for each installation of one display screen installation frame 100, connecting horizontally and fixing the display screen installation frames 100 of the same hierarchical order; the display screen installation frames 100 further includes a third installation side and a fourth installation side;

the third installation side of the display screen installation frames 100 is provided with at least one fastening part 30, the fourth installation side thereof is provided with at least one second U-shaped lock component 40; adjacent display screen installation frames 100 are assembled or disassembled through a cooperation of the fastening part 30 and the second U-shaped lock component 40;
connecting all display screen installation frames 100 in sequence and assembling them into a support frame for a large LED display screen; when each display screen installation frame 100 is installed with an LED display screen, a large LED display screen is assembled

The various technical features of the above embodiments can be combined arbitrarily. In order to render the description concise, not all possible combinations of the various technical features in the above embodiments have been described. However, as long as there is no contradiction in the combination of these technical features, they should be considered within the scope of this specification. The above embodiments only express several embodiments of the present application, and their descriptions are more specific and detailed, but should not be understood as limiting the scope of the present application. It should be noted that for those skilled in the art, several modifications and improvements can be made without departing from the concept of the present application, which are within the protection scope of the present application.

It should be noted that when a component is referred to as “fixed” or “provided” on another component, it can be directly or indirectly provided on another component; when a component is referred to as “connected” to another component, it can be directly or indirectly connected to another component. It should be understood that terms “length”, “width”, “up”, “down”, “front”, “back”, “left”, “right”, “vertical”, “horizontal”, “top”, “bottom”, “inside”, “outside” and other directional or positional relationships indicated are based on the directional or positional relationships shown in the accompanying drawings, and are only for a convenience of describing and simplifying the present application, and do not indicate or imply that the device or component referred to must have a specific orientation, be constructed and operated in a specific orientation, and therefore cannot be understood as a limitation on the present application.

In addition, terms “first” and “second” are only used for descriptive purposes and cannot be understood as indicating or implying relative importance or implying the number of technical features indicated. Thus, the features limited to “first” and “second” may explicitly or implicitly include one or more of these features. In the description of the present application, the meanings of “a plurality of” and “several” refer to two or more, unless otherwise specified.

Note that the structure, proportion, size, etc. shown in the accompanying drawings of this specification are only for the purpose of cooperating with the content disclosed in the specification, for the understanding and reading of those familiar with this technology, and are not intended to limit the conditions that can be implemented in the present application. Therefore, they do not have substantive technical significance. Any modification of the structure, change in proportion relationship, or adjustment of size should still fall within the scope of the technical content disclosed in the present application without affecting the efficacy and purpose that can be achieved.

What is claimed is:

1. An LED display installation system, comprising a plurality of display installation frames, and each display installation frame is capable of installing an LED display screen;
the display screen installation frames comprise a first installation side and a second installation side; the first installation side of the display screen installation frames is provided with at least one curvature lock component, the second installation side of the display screen installation frames is provided with at least one U-shaped lock component; adjacent display screen installation frames are connected through a cooperation of the curvature lock component and the U-shaped lock component;
the display screen installation frames further comprise a third installation side and a fourth installation side; the third installation side of the display screen installation frames is provided with at least one fastening part, the fourth installation side thereof is provided with at least one second U-shaped lock component; adjacent display screen installation frames are assembled or disassembled by a cooperation of the fastening part and the second U-shaped lock component;
the plurality of display screen installation frames are connected horizontally through the first installation side and the second installation side, are connected vertically through the third installation side and the fourth installation side, and are assembled into a support frame for a large LED display screen.

2. The LED display installation system according to claim 1, wherein rears of the display screen installation frames are further provided with an LED display screen box windproof bracket, which comprises a main suspension frame on the same plane and an auxiliary bracket provided at one side of the main suspension frame;
the auxiliary bracket is accommodated in the plane of the main suspension frame, the main suspension frame is capable of being unfolded and fixed in an unfolded posture to form a three-dimensional support mechanism.

3. The LED display installation system according to claim 1, wherein the display screen installation frames are capable of installing an LED display screen carrier, and the LED display screen carrier comprises a carrier body;
a bearing surface of the carrier body is provided with a plurality of first positioning structures, the first positioning structures are adapted to a second positioning structure of modular load-bearing objects;
two opposite sides of the modular load-bearing objects are respectively provided with the first positioning structures and the second positioning structure;
adjacent modular load-bearing objects are spliced together through the first positioning structures and the second positioning structure.

4. The LED display installation system according to claim 1, further comprising a carrier body, a bearing surface of the carrier body is provided with a plurality of first positioning structures, which are adapted to a second positioning structure of modular load-bearing objects;
two opposite sides of the modular load-bearing objects are respectively provided with the first positioning structures and the second positioning structure, adjacent modular load-bearing objects are spliced together through the first positioning structures and the second positioning structure.

5. An installation method for an LED display screen, comprising the following steps:
obtaining a position of a suspension beam and sequentially installing display screen installation frames along a vertical direction below the suspension beam, wherein the display screen installation frames are capable of installing an LED display screen, the display screen installation frames comprise a first installation side and a second installation side, the first installation side of the display screen installation frames is provided with at least one curvature lock component, the second installation side of the display screen installation frames is provided with at least one U-shaped lock component, adjacent display screen installation frames are connected through a cooperation of the curvature lock component and the U-shaped lock component;
a bottom of the suspension beam is provided with a curvature lock component that is the same as the first installation side of the display screen installation frames; the display screen installation frames are connected through a corporation of the curvature lock component and the U-shaped lock component; or
a bottom of the suspension beam is provided with a U-shaped lock component that is the same as the second installation side of the display screen installation frames, and the display screen installation frames are connected through a cooperation of the curvature lock component and the U-shaped lock component;
defining a hierarchical order of the display screen installation frame for each installation of one display screen installation frame, connecting horizontally and fixing the display screen installation frames of the same hierarchical order; the display screen installation frames further comprise a third installation side and a fourth installation side; the third installation side of the display screen installation frames is provided with at least one fastening part, the fourth installation side thereof is provided with at least one second U-shaped lock component; adjacent display screen installation frames are assembled or disassembled through a cooperation of the fastening part and the second U-shaped lock component;
connecting all display screen installation frames in sequence and assembling them into a support frame for a large LED display screen; when each display screen installation frame is installed with an LED display screen, a large LED display screen is assembled.
